(19) United States
(12) Patent Application Publication
(10) Pub. No.: US 2022/0199885 A1
(43) Pub. Date: Jun. 23, 2022

(54) THERMOELECTRIC MODULE

(71) Applicant: KELK Ltd., Kanagawa (JP)

(72) Inventor: JO YAZAKI, Kanagawa (JP)

(21) Appl. No.: 17/644,859

(22) Filed: Dec. 17, 2021

(30) Foreign Application Priority Data
Dec. 21, 2020 (JP) 2020211745

(51) Int. Cl. H01L 35/32

(52) U.S. Cl. CPC H01L 35/32

(57) ABSTRACT

A thermoelectric module includes a first substrate and a second substrate, which are a pair of substrates, and a plurality of thermoelectric conversion elements disposed between the first substrate and the second substrate, which are the pair of substrates, and types of the plurality of thermoelectric conversion elements defined by at least one of shapes and materials being different.

### CROSS-REFERENCE TO RELATED APPLICATION(S)

The present application claims priority to and incorporates by reference the entire contents of Japanese Patent Application No. 2020-211745 filed in Japan on Dec. 21, 2020.

### BACKGROUND OF THE INVENTION

### 1. Field of the Invention

The present invention relates to a thermoelectric module.

### 2. Description of the Related Art

JP 2019-140306 A discloses a temperature adjuster that adjusts the temperature of a wavelength-variable laser element with a Peltier effect. This technique includes a lower substrate, a plurality of thermoelectric conversion elements provided in different regions on the upper surface of the lower substrate at a predetermined distance, and a plurality of upper substrates provided on the upper surfaces of each of the plurality of thermoelectric conversion elements provided in the different regions. Wavelength-conversion laser elements are provided on the upper surfaces of each of the plurality of upper substrates.

In the description of JP 2019-140306 A, the thermoelectric conversion elements disposed between a pair of substrates have the same shape and material. When the temperatures of a plurality of temperature control targets are adjusted, it is necessary to arrange one or more temperature control targets in a plurality of temperature controllers or to arrange all the temperature control targets in one temperature controller. When the plurality of temperature controllers are disposed, the number of components increases. When all the temperature control targets are disposed in one temperature controller, the thermoelectric conversion elements are the same, and thus the power consumption and the heat absorption capacity of the temperature controller may not be optimized.

The present invention provides a thermoelectric module capable of appropriately adjusting the temperature of a temperature control target.

### SUMMARY OF THE INVENTION

It is an object of the present invention to at least partially solve the problems in the conventional technology.

According to an aspect of the present invention, a thermoelectric module comprises; a pair of substrates; and a plurality of thermoelectric conversion elements disposed between the pair of substrates, types of the plurality of thermoelectric conversion elements defined by at least one of shapes and materials being different.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic view illustrating an example of a thermoelectric module according to an embodiment;

FIG. 2 is a view for explaining a method of selecting a thermoelectric conversion element; and

FIG. 3 is a schematic view illustrating an example of a thermoelectric module of related art.

### DETAILED DESCRIPTION OF THE PREFERRED EMBODIMENTS

An embodiment according to the present disclosure is explained below with reference to the drawings. However, the present disclosure is not limited to this. Components of the embodiment explained below can be combined as appropriate. A part of the components is sometimes not used.

In the embodiment, the positional relationship of respective parts is explained using terms “left”, “right”, “front”, “rear”, “upper”, and “lower”. These terms indicate the relative positions or directions with respect to the center of a thermoelectric module 1. The left-right direction, the front-rear direction, and the up-down direction are orthogonal to one another.

### EMBODIMENT

Thermoelectric Module

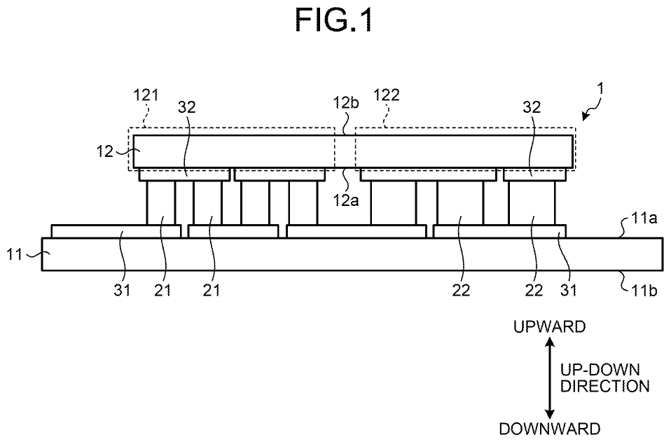

FIG. 1 is a schematic view illustrating an example of a thermoelectric module according to an embodiment. The thermoelectric module 1 absorbs heat or generates heat with the Peltier effect. The thermoelectric module 1 absorbs heat or generates heat to adjust the temperature of a temperature control target. In the embodiment, the thermoelectric module 1 is explained as a thermoelectric cooler that adjusts the temperatures of a plurality of temperature control targets such as optical elements.

The thermoelectric module 1 includes a first substrate 11 and a second substrate 12, which are a pair of substrates, a plurality of types of thermoelectric conversion elements, a first electrode 31, and a second electrode 32. In the embodiment, the plurality of types of thermoelectric conversion elements are explained as two types of thermoelectric conversion elements 21 and 22. The plurality of types of thermoelectric conversion elements is not limited this.

The first substrate 11 and the second substrate 12 are plate-like substrates. In the embodiment, the first substrate 11 and the second substrate 12 are formed in rectangular shapes. The first substrate 11 and the second substrate 12 are formed of an electrically insulating material such as ceramics. The first substrate 11 and the second substrate 12 are formed of a material having high thermal conductivity.

The first substrate 11 is disposed on the lower side. The first substrate 11 has a surface 11a disposed to face the second substrate 12 and a surface 11b disposed to face the opposite side of the surface 11a. The surface 11a and the surface 11b are parallel to each other.

The second substrate 12 is disposed at an interval while facing the first substrate 11. The second substrate 12 is parallel to the first substrate 11. The second substrate 12 is disposed above the first substrate 11 in FIG. 1. The second substrate 12 has a surface 12a disposed to face the first substrate 11 and a surface 12b disposed to face the opposite side of the surface 12a. The surface 12a and the surface 12b are parallel to each other. In the second substrate 12, a temperature control target is disposed on the surface 12b. In the embodiment, heat is removed from the second substrate 12 by the Peltier effect. As a result, the temperature control target disposed on the surface 12b is cooled.

A plurality of thermoelectric conversion elements 21 and a plurality of thermoelectric conversion elements 22 are disposed between the surface 11a of the first substrate 11 and the surface 12a of the second substrate 12. The numbers of thermoelectric conversion elements 21 and thermoelectric conversion elements 22 may be the same or may be different. The plurality of thermoelectric conversion elements 21 is referred to as a group of thermoelectric conversion elements 21. The plurality of thermoelectric conversion elements 22 is referred to as a group of thermoelectric conversion elements 22. The group of thermoelectric conversion elements 21 and the group of thermoelectric conversion elements 22 are disposed in different regions between the surface 11a of the first substrate 11 and the surface 12a of the second substrate 12. The group of thermoelectric conversion elements 21 and the group of thermoelectric conversion elements 22 may be disposed at an interval. The interval prevents the heat of the group of thermoelectric conversion elements 21 and the heat of the group of thermoelectric conversion elements 22 from interfering with each other.

The thermoelectric conversion element 21 and the thermoelectric conversion element 22 absorb heat or generate heat with the Peltier effect. The thermoelectric conversion element 21 and the thermoelectric conversion element 22 have a prismatic shape, the cross section of which in the axial direction is rectangular.

A thermoelectric conversion element 133 is made of a thermoelectric material. The thermoelectric conversion element 21 and the thermoelectric conversion element 22 include, for example, a thermoelectric material containing at least two kinds of elements among bismuth (Bi), antimony (Sb), tellurium (Te), and selenium (Se) as main components and a material serving as a dopant. The thermoelectric conversion element 21 and the thermoelectric conversion element 22 are formed of, for example, a Bi—Te-based, Bi—Se-based, Sb—Te-based, Bi—Sb-based, or Sb—Se-based thermoelectric material.

The thermoelectric conversion element 21 includes a p-type element formed of a p-type semiconductor thermoelectric material and an n-type element formed of an n-type semiconductor thermoelectric material. Examples of the Bi—Te-based thermoelectric material forming the p-type element include thermoelectric materials containing Bi, Te, and Sb. Examples of the Bi—Te-based thermoelectric material forming the n-type element include thermoelectric materials containing Bi, Te, and Se. A plurality of p-type elements and a plurality of n-type elements are disposed in a predetermined plane. The p-type element and the n-type element are alternately disposed in the front-rear direction. The p-type element and the n-type element are alternately disposed in the left-right direction.

The thermoelectric conversion element 22 includes a p-type element and an n-type element. In the thermoelectric conversion element 22 as well, the p-type element and the n-type element are alternately disposed.

The thermoelectric conversion element 21 and the thermoelectric conversion element 22 are different in at least one of shape and material. The types of the thermoelectric conversion element 21 and the thermoelectric conversion element 22 are defined by at least one of shapes and materials. When the thermoelectric conversion element 21 and the thermoelectric conversion element 22 are compared and at least one of the shape and the material is different, this is referred to as “different in type”. More specifically, when the thermoelectric conversion element 21 and the thermoelectric conversion element 22 are compared and at least any one of the axial length, the length of one side in the cross section perpendicular to the axial direction, and the length of the other side is different by, for example, 0.01 mm or more, this is referred to as “different in type”. When the thermoelectric conversion element 21 and the thermoelectric conversion element 22 are compared and the thermoelectric conversion element 21 and the thermoelectric conversion element 22 are different in material, this is referred to as “different in type”.

The thermoelectric conversion element 21 and the thermoelectric conversion element 22 of different types have different power consumption and different heat absorption capabilities when driven with the same driving current.

The first electrode 31 and the second electrode 32 are formed of, for example, metal having high electrical conductivity and thermal conductivity. Examples of the metal forming the first electrode 31 and the second electrode 32 include copper (Cu), an alloy containing copper, nickel (Ni), an alloy containing nickel, aluminum (Al), an alloy containing aluminum, palladium (Pd), an alloy containing palladium, gold (Au), and an alloy containing gold. The first electrode 31 and the second electrode 32 may have a two-layer or three-layer structure in which two or three of Cu, Al, Ni, Pd, and Au are combined. The surfaces of the first electrode 31 and the second electrode 32 may be covered with a nickel film.

The first electrode 31 is provided on the surface 11a of the first substrate 11. A plurality of the first electrodes 31 are aligned in a predetermined plane parallel to the surface 11a of the first substrate 11. The second electrode 32 is provided on the surface 12a of the second substrate 12. A plurality of the second electrodes 32 are aligned in a predetermined plane parallel to the surface 12a of the second substrate 12. The first electrode 31 and the second electrode 32 are disposed to be separated from and opposed to each other while being shifted in position so as to partially overlap each other as viewed in the vertical direction.

The group of thermoelectric conversion elements 21 and the group of thermoelectric conversion elements 22 are disposed between the first electrode 31 and the second electrode 32. More specifically, the first electrode 31 and the second electrode 32 are connected to each of a pair of a p-type element and n-type element adjacent to each other. In this way, the p-type element and the n-type element are electrically connected via the first electrode 31 or the second electrode 32 to form a pn element pair. A not-illustrated lead wire is electrically connected to, via the second electrode 32, the n-type element disposed at the start end of a circuit. A not-illustrated lead wire is electrically connected to, via the second electrode 32, the p-type element disposed at the terminal end of the circuit.

A plurality of pn element pairs of the group of thermoelectric conversion elements 21 are connected in series, in parallel, or partially in parallel to form a series circuit, a parallel circuit, or a partially parallel circuit. A plurality of pn element pairs of the group of thermoelectric conversion elements 22 are connected in series, in parallel, or partially in parallel to form a series circuit, a parallel circuit, or a partially parallel circuit. In other words, the thermoelectric conversion elements 21 and 22 of the same type are electrically connected all in series, all in parallel, or partially in parallel.

Furthermore, the group of thermoelectric conversion elements 21 and the group of thermoelectric conversion elements 22 are connected in series. As a result, the group of thermoelectric conversion elements 21 and the group of thermoelectric conversion elements 22 are driven by the same electric current.

The thermoelectric conversion element 21 and the first electrode 31, the thermoelectric conversion element 21 and the second electrode 32, the thermoelectric conversion element 22 and the first electrode 31, and the thermoelectric conversion element 22 and the second electrode 32 are bonded by solder. When the length in the axial direction of the thermoelectric conversion element 21 and the thermoelectric conversion element 22 are different, the thickness of the solder or the thickness of the electrodes is adjusted. Consequently, the thermoelectric conversion elements 21 and the thermoelectric conversion elements 22 having different lengths in the axial direction can be disposed between the pair of the first substrate 11 and the second substrate 12.

Method of Using the Thermoelectric Module and Action

In the thermoelectric module 1 configured as explained above, when electric power is applied to the thermoelectric element group, the second substrate 12 of the thermoelectric module 1 is cooled and the first substrate 11 is heated by the Peltier effect of the thermoelectric conversion element 21 and the thermoelectric conversion element 22. Since the thermoelectric conversion element 21 and the thermoelectric conversion element 22 are different in type, the surface 12b located in the region 121 of the second substrate 12 where the thermoelectric conversion element 21 is disposed and the surface 12b located in the region 122 of the second substrate 12 where the thermoelectric conversion element 22 is disposed are respectively adjusted to different temperatures.

A first temperature control target, the temperature of which is adjusted by the thermoelectric conversion element 21, is disposed on the surface 121b located in the region 12. A second temperature control target, the temperature of which is adjusted by the thermoelectric conversion element 22, is disposed on the surface 122b located in the region 12.

Method of Selecting a Thermoelectric Conversion Element

Next, an example of a method for selecting a thermoelectric conversion element to be disposed between the first substrate 11 and the second substrate 12, which are a pair of substrates, in the thermoelectric module 1 is explained. A type and a number of couples of the thermoelectric conversion element are selected so as to reduce power consumption based on conditions including at least one of a cooling side temperature, a heat dissipation side temperature, a heat absorption amount, a heat dissipation side thermal resistance, and a cooling side thermal resistance. The number of couples is a number of couples of a pn element pair of the thermoelectric conversion element.

The cooling side temperature, which is the temperature of the second substrate 12 of the thermoelectric module 1, is represented as Tc and the heat dissipation side temperature, which is the temperature of the first substrate 11, is represented as Th. The heat absorption amount of the thermoelectric module 1 is represented as Qc. The heat dissipation side thermal resistance, which is the thermal resistance of the first substrate 11, is represented as θh. The cooling side thermal resistance, which is the thermal resistance of the second substrate 12, is represented as θc. The cooling side temperature Tc, the heat dissipation side temperature Th, the heat absorption amount Qc, the heat dissipation side thermal resistance θh, and the cooling side thermal resistance θc are set based on a cooling capacity corresponding to a temperature control target of the thermoelectric module 1.

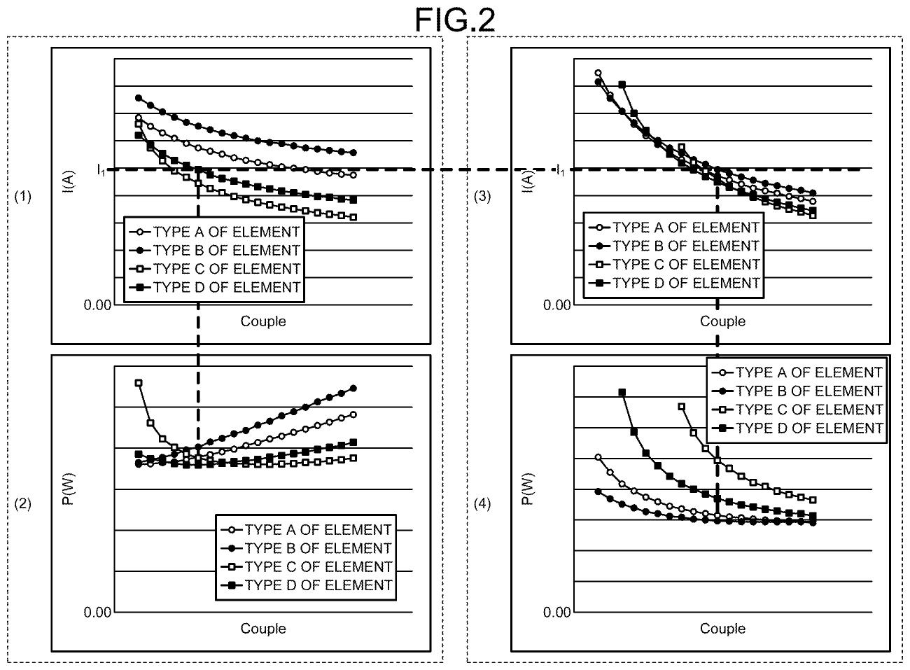

A method for selecting a thermoelectric conversion element is explained in detail with reference to FIG. 2. FIG. 2 is a diagram for explaining a method of selecting a thermoelectric conversion element. In FIGS. 2 (1) and 2 (3), the horizontal axis represents a number of couples of the pn element pair of the thermoelectric conversion element and the vertical axis represents a driving current (A). In FIGS. 2 (2) and 2 (4), the horizontal axis represents the number of couples of the pn element pair of the thermoelectric conversion element and the vertical axis represents power consumption (W). FIGS. 2 (1) and 2 (2) illustrate a condition example 1. FIGS. 2 (3) and 2 (4) illustrate a condition example 2. In both of the condition example 1 and the condition example 2, four types of thermoelectric conversion elements, that is, a type A, a type B, a type C, and a type D, are set as candidates.

When there are a plurality of temperature control targets, conditions including at least one of the cooling side temperature Tc, the heat dissipation side temperature Th, the heat absorption amount Qc, the heat dissipation side thermal resistance θh, and the cooling side thermal resistance θc are set according to the respective temperature control targets. Here, a case where thermoelectric conversion elements suitable for the condition example 1 and the condition example 2 corresponding to two temperature control targets are selected is explained. In the condition example 1 and the condition example 2, a driving current is the same.

In the condition example 1, Tc=Tc₁ (° C.), Th=Th₁ (° C.), and Qc=Qc₁ (W). In addition, it is assumed that the thermoelectric conversion elements are driven by an electric current I₁ (A). In the condition example 1, from FIG. 2 (1), the thermoelectric conversion elements of the type A, the type C, and the type D can be selected at the electric current I₁. The thermoelectric conversion element of the type B is not driven and is not a target. From FIG. 2 (2), among the thermoelectric conversion elements of the type A, the type C, and the type D, the thermoelectric conversion element of the type D has the minimum power consumption. In this way, in the condition example 1, the thermoelectric conversion element of the type D is selected. In addition, from FIGS. 2 (1) and 2 (2), the number of couples of the pn element pair of the thermoelectric conversion element of the type D in the condition example 1 is also determined.

In the condition example 2, Tc=Tc₂ (° C.) (Tc₂>Tc₁), Th=Th₂ (° C.) (Th₂=Th₁), and Qc=Qc₂ (W) (Qc₂>Qc₁). In addition, it is assumed that the thermoelectric conversion elements are driven by the same electric current I₁ (A) as in the condition example 1. In the condition example 2, from FIG. 2 (3), the thermoelectric conversion elements of the type A, the type B, the type C, and the type D can be selected. From FIG. 2 (4), among the thermoelectric conversion elements of the type A, the type B, the type C, and the type D, the thermoelectric conversion element of the type B has the minimum power consumption. In this way, in the condition example 2, the thermoelectric conversion element of the type B is selected. In addition, from FIGS. 2 (3) and 2 (4), a number of couples of the pn element pair of the thermoelectric conversion element of the type B in this case is also determined.

In this way, for the plurality of temperature control targets, it is possible to select appropriate types and number of couples of thermoelectric conversion elements so as to reduce power consumption based on at least one of the cooling side temperature, the heat dissipation side temperature, the heat absorption amount, the heat dissipation side thermal resistance, and the cooling side thermal resistance.

### Effects

In the embodiment, thermoelectric conversion elements of different types can be disposed between the first substrate 11 and the second substrate 12, which are the pair of substrates. According to the embodiment, the temperature of a temperature control target can be appropriately adjusted.

In the embodiment, since a temperature control target ground contact surface is one surface, that is, the surface 12b of the second substrate 12, flatness and parallelism of the ground contact surface can be improved. As a result, in the embodiment, for example, the influence of optical axis deviation can be reduced at the time of setting of the temperature control target, which is an optical element. Further, in the embodiment, the number of components can be reduced and cost can be reduced.

In the embodiment, types and number of couples of thermoelectric conversion elements having optimum power consumptions and heat absorbing capabilities can be respectively selected for a plurality of temperature control targets. According to the embodiment, the temperatures of the plurality of temperature control targets can be appropriately adjusted. Thus, according to the embodiment, power consumption can be reduced.

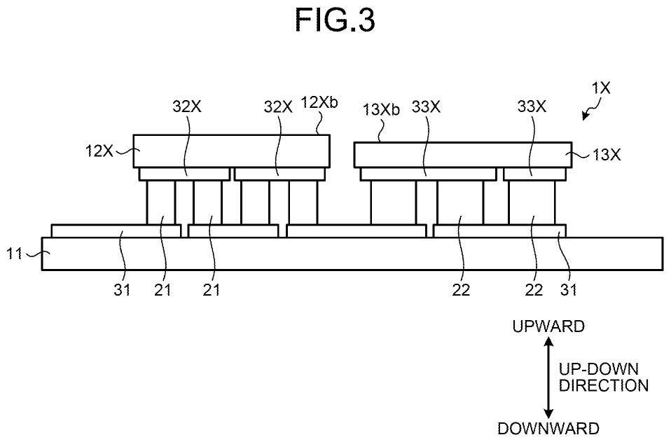

For comparison, a thermoelectric module 1X of related art is explained. FIG. 3 is a schematic view illustrating an example of a thermoelectric module of related art. In the thermoelectric module 1X of related art, a thermoelectric conversion element 22 is disposed between a first substrate 11 and a second substrate 12X via a first electrode 31 and a second electrode 32X. A thermoelectric element 23 is disposed between the first substrate 11 and a second substrate 13X via the first electrode 31 and a second electrode 33X. In the thermoelectric module 1X of related art, temperature control targets are respectively disposed on the second substrate 12X and the second substrate 13X. Since the second substrate 12X and the second substrate 13X are separate members, a surface 12Xb and a surface 13Xb serving as ground contact surfaces are not on the same plane. As a result, for example, when a temperature control target, which is an optical element, is set, it takes labor and time to adjust an optical axis. Furthermore, the number of components increases.

In the above explanation, the present disclosure is used for temperature control of optical equipment including an optical element used for communication or the like. However, the embodiment is also applicable to a thermoelectric generator.

According to an aspect of the present invention, it is possible to provide a thermoelectric module capable of appropriately adjusting the temperature of a temperature control target.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A thermoelectric module comprising:
a pair of substrates; and
a plurality of thermoelectric conversion elements disposed between the pair of substrates, types of the plurality of thermoelectric conversion elements defined by at least one of shapes and materials being different.

2. The thermoelectric module according to claim 1, wherein the thermoelectric conversion elements same in the types are all electrically connected in series, all in parallel, or partially in parallel.

3. The thermoelectric module according to claim 1, wherein, when the plurality of thermoelectric conversion elements same in the types are represented as a group of thermoelectric conversion elements, all of the group of thermoelectric conversion elements are electrically connected in series, all in parallel, or partially in parallel.

4. The thermoelectric module according to claim 1, wherein the thermoelectric conversion elements are disposed in a type and a number of couples with small power consumption based on at least one of a cooling side temperature, a heat dissipation side temperature, a heat absorption amount, a heat dissipation side thermal resistance, and a cooling side thermal resistance.
